(19) United States
(12) Patent Application Publication
(10) Pub. No.: US 2009/0230538 A1
(43) Pub. Date: Sep. 17, 2009

(54) SEMICONDUCTOR CHIP PACKAGE STRUCTURE FOR ACHIEVING FACE-UP ELECTRICAL CONNECTION WITHOUT USING A WIRE-BONDING PROCESS AND METHOD FOR MAKING THE SAME

(75) Inventors: BILY WANG, HSINCHU CITY (TW); SUNG-YI HSIAO, MIAOLI COUNTY (TW); YUN-HAO CHANG, MIAOLI COUNTY (TW); JACK CHEN, MIAOLI COUNTY (TW)

Correspondence Address: ROSENBERG, KLEIN & LEE, 3458 ELLICOTT CENTER DRIVE-SUITE 101, ELLICOTT CITY, MD, 21043, US

(73) Assignee: HARVATEK CORPORATION, HSINCHU CITY (TW)

(21) Appl. No.: 12/243,274

(22) Filed: Oct. 1, 2008

(30) Foreign Application Priority Data
Mar. 14, 2008 (TW) 97109187

(51) Int. Cl. H01L 23/12; H01L 21/50

(52) U.S. Cl. 257/690; 438/106; 257/E23.003; 257/E21.499

(57) ABSTRACT

A semiconductor chip package structure for achieving face-up electrical connection without using a wire-bonding process includes a package unit, a semiconductor chip, a substrate unit, a first insulative unit, a first conductive unit, a second conductive unit, and a second insulative unit. The package unit has a central receiving groove and an outer receiving groove formed around the central receiving groove. The semiconductor chip has a plurality of conductive pads. The first insulative unit has a first insulative layer formed between the conductive pads. The first conductive unit has a plurality of first conductive layers. The second conductive unit has a plurality of second conductive layers formed on the first conductive layers. The second insulative unit is formed between the first conductive layers and between the second conductive layers.

### BACKGROUND OF THE INVENTION

1. Field of the Invention

The present invention relates to a semiconductor chip package structure and a method for making the same, and particularly relates to a semiconductor chip package structure for achieving face-up electrical connection without using a wire-bonding process and a method for making the same.

2. Description of Related Art

Referring to FIG. 1, a known LED package structure that is packaged via a wire-bonding process. The known LED package structure includes a substrate 1, an LED (light emitting diode) 2 disposed on the substrate, two wires 3, and a fluorescent colloid 4.

The LED 2 has a light-emitting surface 20 opposite to the substrate 1. The LED 2 has a positive pole area 21 and a negative pole area 22 electrically connected to two corresponding positive and negative pole areas 11, 12 of the substrate 1 via the two wires 3 respectively. Moreover, the fluorescent colloid 4 is covering on the LED 2 and the two wires 3 for protecting the LED 2.

However, the method of the prior art not only increases manufacture time and cost, but also leads to uncertainty about the occurrence of bad electrical connections in the LED package structure of the prior art resulting from the wire-bonding process. Moreover, the two sides of the two wires 3 are respectively disposed on the positive and negative pole areas 21, 22. Hence, when the light of the LED 2 is projected outwardly from the light-emitting surface 20 and through the fluorescent colloid 4, the two wires 3 will produce two shadow lines within the light emitted by the LED 2 and thus affect the LED's light-emitting efficiency.

### SUMMARY OF THE INVENTION

One particular aspect of the present invention is to provide a semiconductor chip package structure for achieving face-up electrical connection without using a wire-bonding process and a method for making the same. Because the semiconductor chip package structure of the present invention can achieve electrical connection without using a wire-bonding process, the present invention can omit the wire-bonding process and avoid bad electrical connection in the semiconductor chip package structure.

In order to achieve the above-mentioned aspects, the present invention provides a semiconductor chip package structure for achieving face-up electrical connection without using a wire-bonding process, including: a package unit, at least one semiconductor chip, a substrate unit, a first insulative unit, a first conductive unit, a second conductive unit, and a second insulative unit. The package unit has at least one central receiving groove and at least one outer receiving groove formed around the at least one central receiving groove. The least one semiconductor chip is received in the at least one central receiving groove and has a plurality of conductive pads disposed on its top surface. The substrate unit is received in the at least one outer receiving groove.

Moreover, the first insulative unit has at least one first insulative layer formed between the conductive pads in order to insulate the conductive pads from each other. The first conductive unit has a plurality of first conductive layers. One of the first conductive layers is formed on the at least one first insulative layer and over the at least one semiconductor chip, and end sides of the other first conductive layers are respectively and electrically connected to the conductive pads. The second conductive unit has a plurality of second conductive layers. One of the second conductive layer is formed on the first conductive layer that has been formed over the at least one semiconductor chip, and the other second conductive layers are respectively and electrically connected to the first conductive layers that have been respectively and electrically connected to the conductive pads. The second insulative unit is formed between the first conductive layers and between the second conductive layers in order to insulate the first conductive layers from each other and insulate the second conductive layers from each other.

In order to achieve the above-mentioned aspects, the present invention provides a method of making semiconductor chip package structures for achieving face-up electrical connection without using a wire-bonding process, including: providing at least two semiconductor chips, wherein each semiconductor chip has a plurality of conductive pads; adhering an adhesive polymeric material on a bottom surface of a substrate unit with at least two through holes; arranging the at least two semiconductor chips in the at least two through holes and on the adhesive polymeric material, wherein the conductive pads face the adhesive polymeric material; and covering the substrate, the adhesive polymeric material and the at least two semiconductor chips with a package unit.

The method further includes: overturning the package unit and removing the adhesive polymeric material in order to make the conductive pads exposed face-up; forming a first conductive unit having a plurality of first conductive layers, wherein two of the first conductive layers is formed on the at least two semiconductor chips, and end sides of the other first conductive layers are respectively and electrically connected to the conductive pads; forming a second conductive unit having a plurality of second conductive layers, wherein two of the second conductive layers is formed on the two first conductive layers that have been formed on the at least two semiconductor chips, and the other second conductive layers are respectively and electrically connected to the first conductive layers that have been respectively and electrically connected to the conductive pads; forming an insulative unit having a plurality of insulative layers, wherein the insulative unit is formed between the first conductive layers and between the second conductive layers in order to insulate the first conductive layers from each other and insulate the second conductive layers from each other; and cutting the second conductive unit, the first conductive unit, the substrate unit and the package unit in sequence in order to form at least two semiconductor chip package structures.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a side, schematic view of an LED package structure via a wire-bonding process according to the prior art;

FIG. 2 is a flowchart of a method of making semiconductor chip package structures for achieving face-up electrical connection without using a wire-bonding process according to the first embodiment of the present invention;

FIGS. 2A to 2K are cross-sectional, schematic views of two semiconductor chip package structures for achieving face-up electrical connection without using a wire-bonding process according to the first embodiment of the present invention, at different stages of the packaging processes, respectively;

FIG. 3 is a flowchart of a method of making semiconductor chip package structures for achieving face-up electrical connection without using a wire-bonding process according to the second embodiment of the present invention;

FIGS. 3A to 3K are partial, cross-sectional, schematic views of two semiconductor chip package structures for achieving face-up electrical connection without using a wire-bonding process according to the second embodiment of the present invention, at different stages of the packaging processes, respectively;

FIGS. 4A to 4C are partial, cross-sectional, schematic views of a first insulative layer formed on a semiconductor chip according to the second embodiment of the present invention, at different stages of the manufacturing processes, respectively.

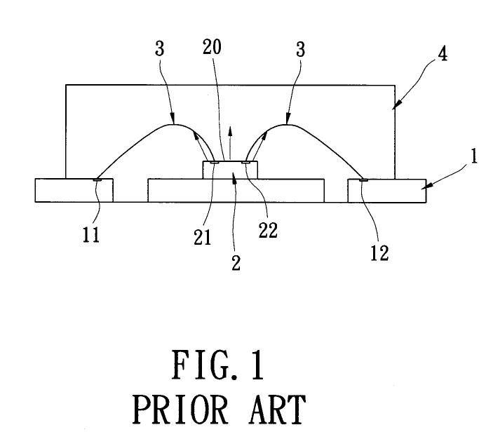

### DETAILED DESCRIPTION OF PREFERRED EMBODIMENTS

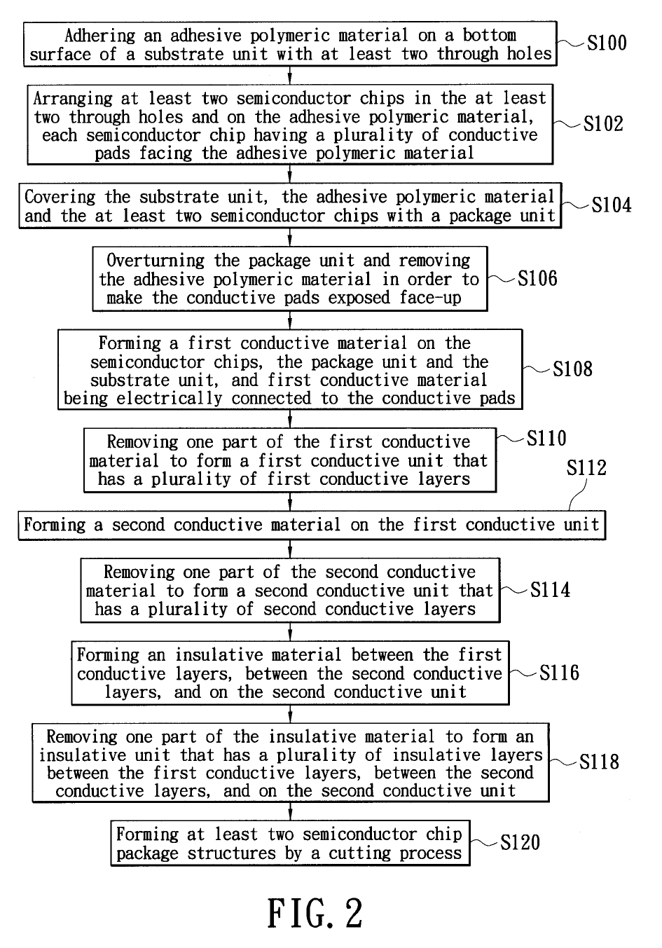

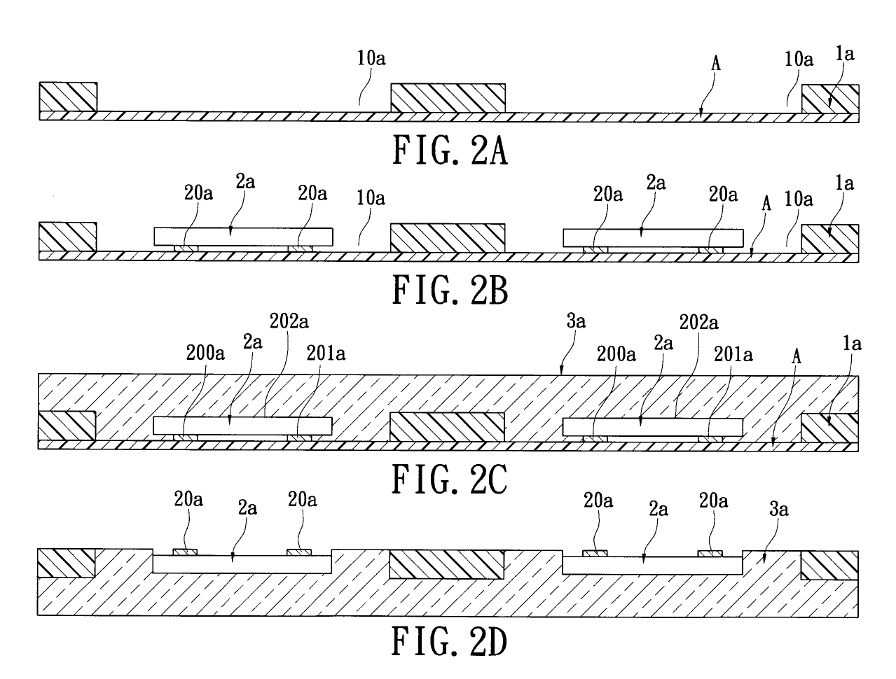

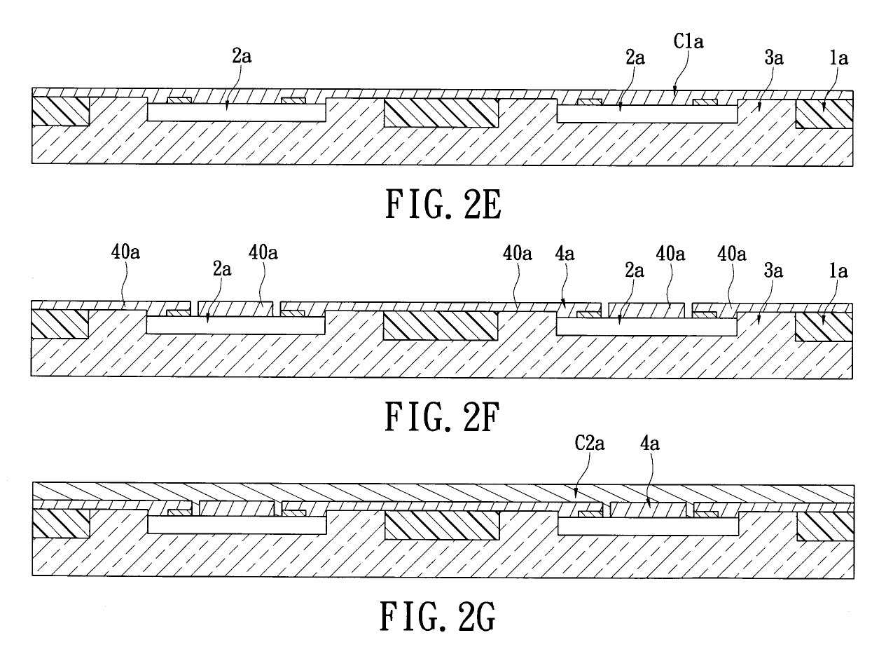

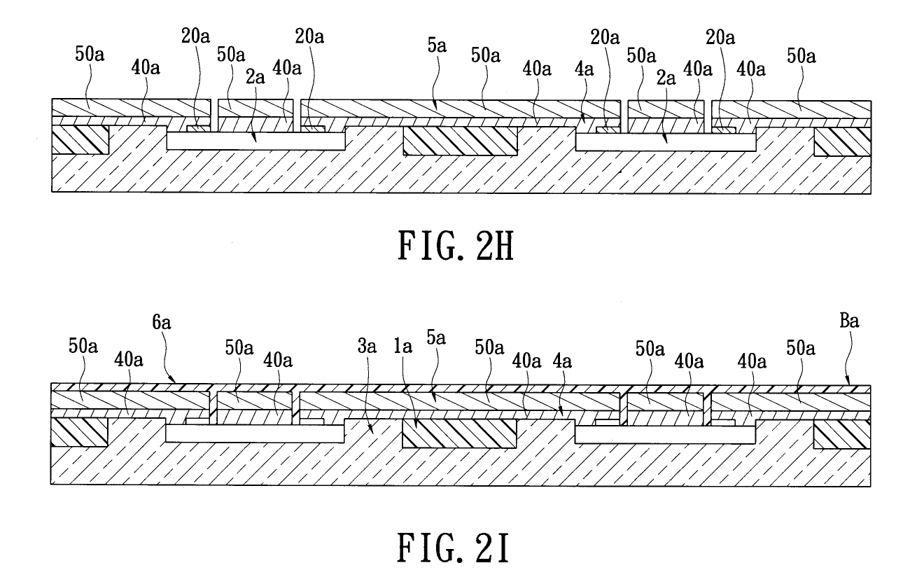

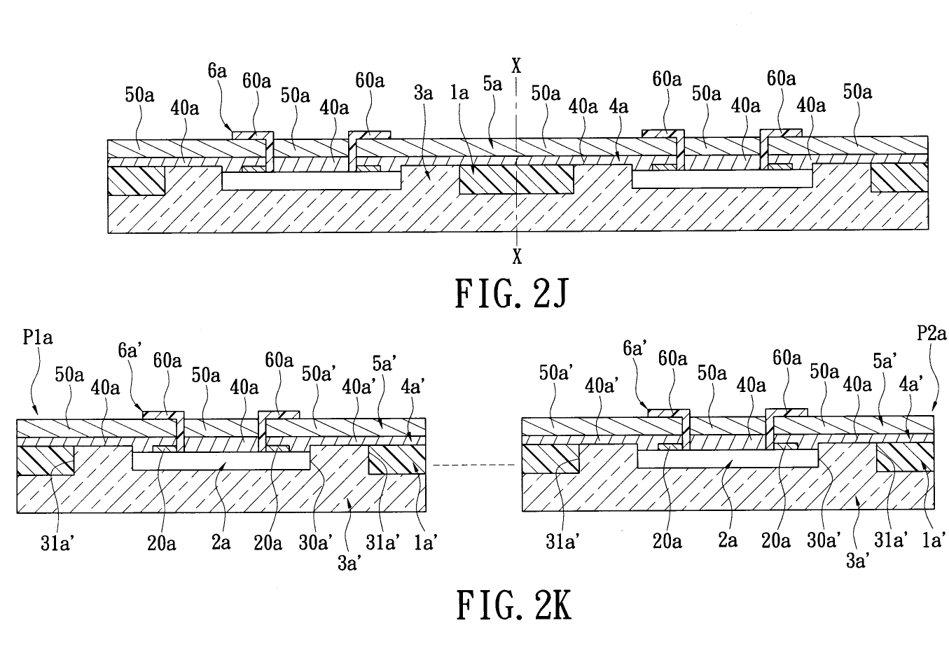

Referring to FIGS. 2 and 2A-2K, the first embodiment of the present invention provides a method of making semiconductor chip package structures for achieving face-up electrical connection without using a wire-bonding process, including as follows:

Step S100 is: referring to FIGS. 2 and 2A, adhering an adhesive polymeric material A on a bottom surface of a substrate unit la with at least two through holes 10a.

Step S102 is: referring to FIGS. 2 and 2B, arranging at least two semiconductor chips 2a in the at least two through holes 10a and on the adhesive polymeric material A, each semiconductor chip 2a having a plurality of conductive pads 20a facing the adhesive polymeric material A. In the first embodiment, each semiconductor chip 2a can be an LED (light emitted diode) chip set.

Step S104 is: referring to FIGS. 2 and 2C, covering the substrate unit 1a, the adhesive polymeric material A and the at least two semiconductor chips 2a with a package unit 3a. In the first embodiment, the package unit 3a can be made from fluorescent material, the conductive pads 20a of each semiconductor chip 2a are divided into a positive pad 200a and a negative pad 201a, and each semiconductor chip 2a has a light-emitting surface 202a on its bottom surface and opposite to the conductive pads 20a.

Step S106 is: referring to FIGS. 2 and 2D, overturning the package unit 3a and removing the adhesive polymeric material A in order to make the conductive pads 20a exposed face-up.

Step S108 is: referring to FIGS. 2 and 2E, forming a first conductive material C1a on the semiconductor chips 2a, the package unit 3a and the substrate unit 1a, and first conductive material C1a being electrically connected to the conductive pads 20a. In addition, the first conductive material C1a is formed on the semiconductor chips 2a, the package unit 3a and the substrate unit 1a by evaporating, sputtering, electroplating or electroless plating.

Step S110 is: referring to FIGS. 2 and 2F, removing one part of the first conductive material C1a to form a first conductive unit 4a that has a plurality of first conductive layers 40a, two of the first conductive layers 40a being formed on the at least two semiconductor chips 20a, and end sides of the other first conductive layers 40a being respectively and electrically connected to the conductive pads 20a. The first conductive unit 4a is a UBM (Under Bump Metallization). In addition, the one part of the first conductive material C1a is removed by matching an exposure process, a development process and an etching process.

Step S112 is: referring to FIGS. 2 and 2G, forming a second conductive material C2a on the first conductive unit 4a. In addition, the second conductive material C2a is formed on the first conductive unit 4a by evaporating, sputtering, electroplating or electroless plating.

Step S114 is: referring to FIGS. 2 and 2H, removing one part of the second conductive material C2a to form a second conductive unit 5a that has a plurality of second conductive layers 50a, two of the second conductive layers 50a being formed on the two first conductive layers 40a that have been formed on the at least two semiconductor chips 2a, and the other second conductive layers 50a being respectively and electrically connected to the first conductive layers 40a that have been respectively and electrically connected to the conductive pads 20a. In addition, the one part of the second conductive material C2a is removed by matching an exposure process, a development process and an etching process.

Step S116 is: referring to FIGS. 2 and 2I, forming an insulative material Ba between the first conductive layers 40a, between the second conductive layers 50a, and on the second conductive unit 5a. In addition, the insulative material Ba is formed by printing, coasting or spraying, and the insulative material Ba is hardened by pre-curing.

Step S118 is: referring to FIGS. 2 and 2J, removing one part of the insulative material Ba to form an insulative unit 6a that has a plurality of insulative layers 60a between the first conductive layers 40a, between the second conductive layers 50a, and on the second conductive unit 5a in order to insulate the first conductive layers 40a from each other and insulate the second conductive layers 50a from each other. In addition, the one part of the insulative material Ba is removed by matching an exposure process, a development process and an etching process to form the insulative layers 60a that are hardened by curing.

Step S120 is: referring to FIGS. 2 and 2K, forming at least two semiconductor chip package structures (P1a, P2a) by a cutting process along the dotted line X-X in FIG. 2J. In other words, the at least two semiconductor chip package structures (P1a, P2a) are formed by cutting the second conductive unit 5a, the first conductive unit 4a, the substrate unit 1a and the package unit 3a in sequence.

Therefore, each semiconductor chip package structure (P1a, P2a) has a package unit 3a′, a semiconductor chip 2a, a substrate unit 1a′, a first conductive unit 4a′, a second conductive unit 5a′, and an insulative unit 6a′.

The package unit 3a′ has at least one central receiving groove 30a′ and at least one outer receiving groove 31a′ formed around the at least one central receiving groove 30a′. The semiconductor chip 2a is received in the at least one central receiving groove 30a′ and has a plurality of conductive pads 20a disposed on its top surface. The substrate unit 1a′ is received in the at least one outer receiving groove 31a′.

Moreover, the first conductive unit 4a′ has a plurality of first conductive layers (40a, 40a′) formed on the semiconductor chip 2a, the package unit 3a′ and the substrate unit 1a′. One of the first conductive layers 40a is formed on the semiconductor chip 2a, and end sides of the other first conductive layers (40a, 40a′) are respectively and electrically connected to the conductive pads 20a. The second conductive unit 5a′ has a plurality of second conductive layers (50a, 50a′). One of the second conductive layer 50a is formed on the first conductive layer 40a that has been formed on the semiconductor chip 2a, and the other second conductive layers (50a, 50a′) are respectively and electrically connected to the first conductive layers (40a, 40a′) that have been respectively and electrically connected to the conductive pads 20.

Furthermore, the insulative unit 6a′ has a plurality of insulative layers 60a that are formed between the first conductive layers (40a, 40a′) and between the second conductive layers (50a, 50a′) in order to insulate the first conductive layers (40a, 40a′) from each other and insulate the second conductive layers (50a, 50a′) from each other. In addition, one part of each insulative layer 60a is covering the second conductive layers (50a, 50a′).

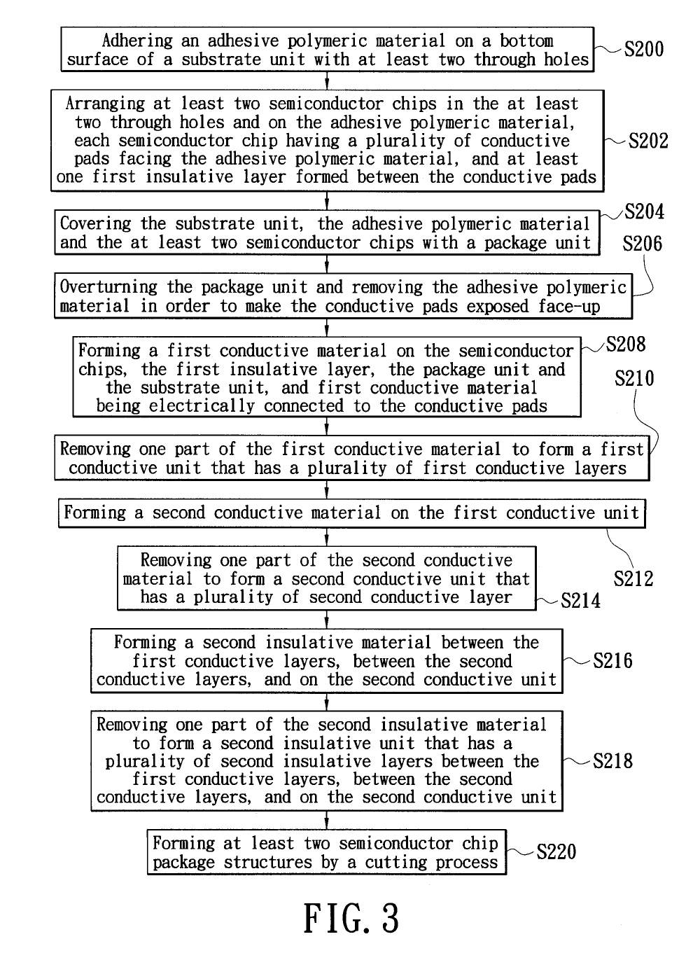

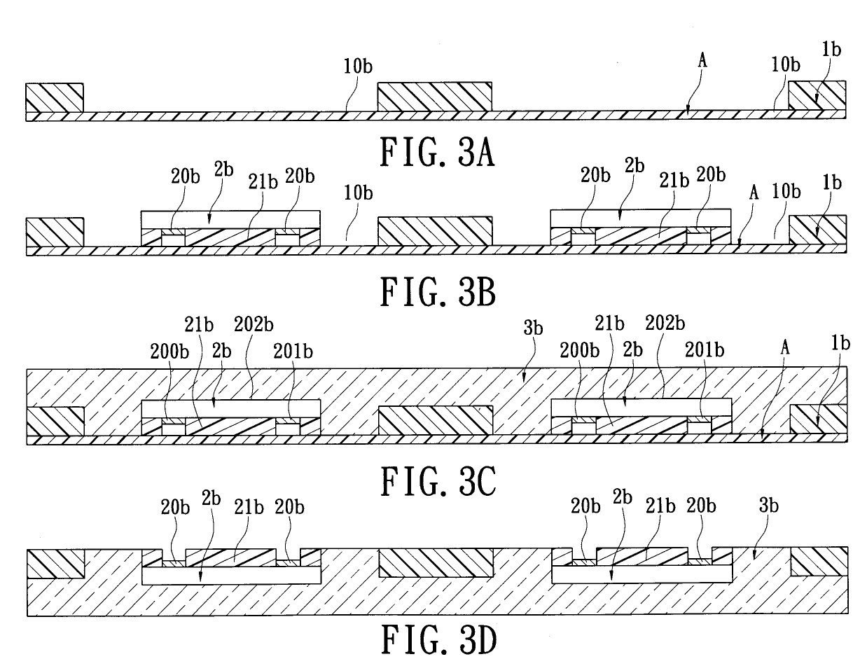

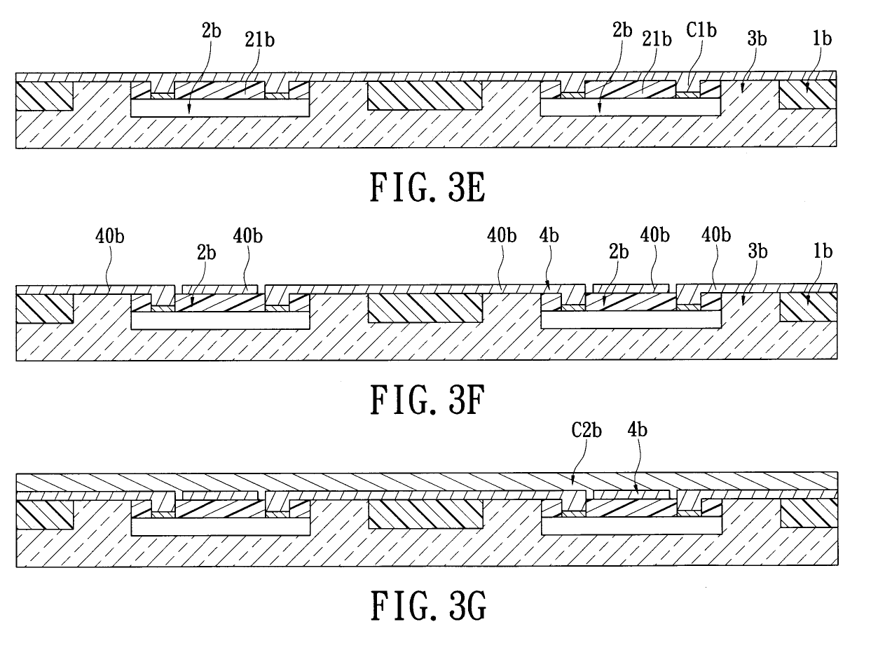

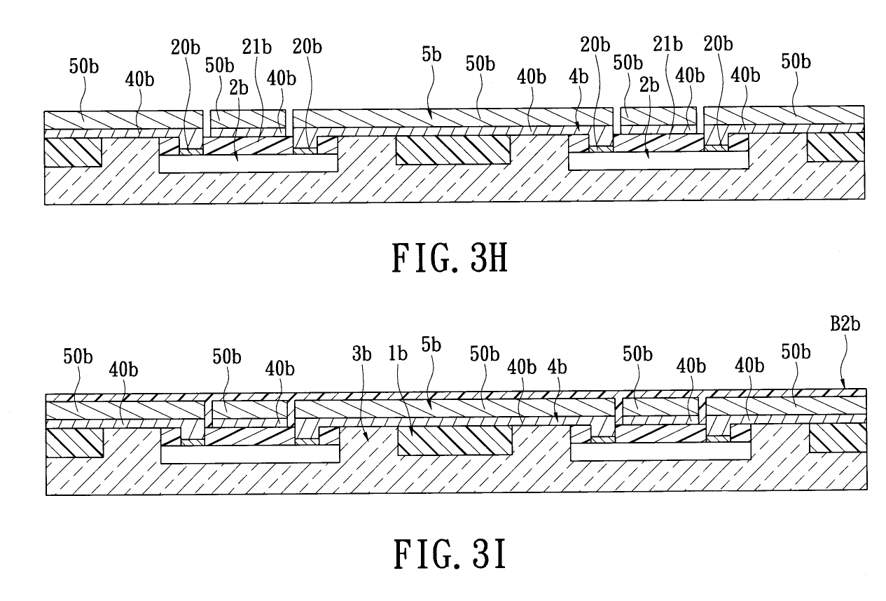

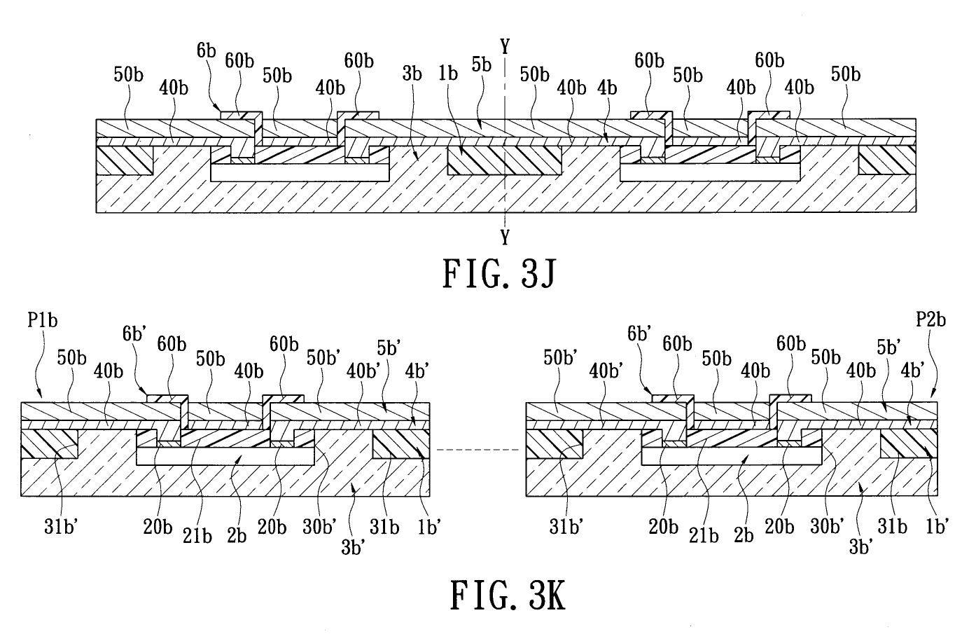

Referring to FIGS. 3 and 3A-3K, the second embodiment of the present invention provides a method of making semiconductor chip package structures for achieving face-up electrical connection without using a wire-bonding process, including as follows:

Step S200 is: referring to FIGS. 3 and 3A, adhering an adhesive polymeric material A on a bottom surface of a substrate unit 1b with at least two through holes 10b.

Step S202 is: referring to FIGS. 3 and 3B, arranging at least two semiconductor chips 2b in the at least two through holes 10b and on the adhesive polymeric material A, each semiconductor chip 2b having a plurality of conductive pads 20b facing the adhesive polymeric material A, and at least one first insulative layer 21b formed between the conductive pads 20b. In the first embodiment, each semiconductor chip 2a can be an LED (light emitted diode) chip set.

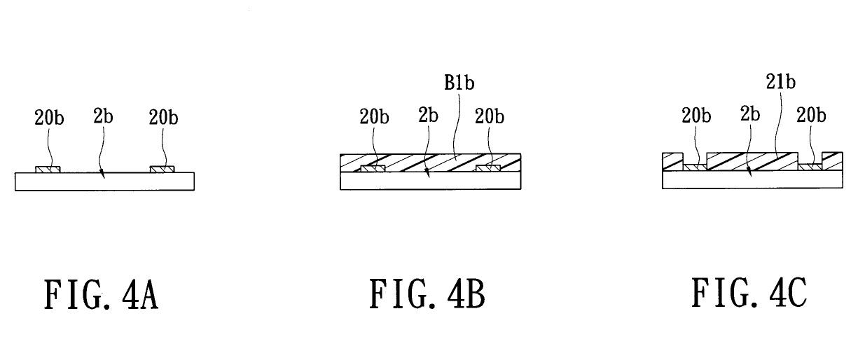

The method for forming the at least one first insulative layer 21b includes (Referring to FIGS. 4A to 4C): firstly, providing a semiconductor chip 2b having a plurality of conductive pads 20b; forming a first insulative materials B1b on the semiconductor chip 2b and on the conductive pads 20b; and then removing one part of the first insulative material B1b to form the first insulative layer 21b (a first insulative unit) between the conductive pads 20b for exposing the conductive pads 20b. In addition, the first insulative material B1b is formed on the semiconductor chip 2b and the conductive pads 20b by printing, coasting or spraying, and the first insulative material B1b is hardened by pre-curing and the one part of the first insulative material B1b is removed by matching an exposure process, a development process and an etching process to form the first insulative layer 21b that is hardened by curing.

Step S204 is: referring to FIGS. 3 and 3C, covering the substrate unit 1b, the adhesive polymeric material A and the at least two semiconductor chips 2b with a package unit 3b. In the second embodiment, the package unit 3b can be made from fluorescent material, the conductive pads 20b of each semiconductor chip 2b are divided into a positive pad 200b and a negative pad 201b, and each semiconductor chip 2b has a light-emitting surface 202b on its bottom surface and opposite to the conductive pads 20b.

Step S206 is: referring to FIGS. 3 and 3D, overturning the package unit 3b and removing the adhesive polymeric material A in order to make the conductive pads 20b exposed face-up.

Step S208 is: referring to FIGS. 3 and 3E, forming a first conductive material C1b on the semiconductor chips 2b, the first insulative layer 21b, the package unit 3b and the substrate unit 1b, and first conductive material C1b being electrically connected to the conductive pads 20b. In addition, the first conductive material C1b is formed on the semiconductor chips 2b, the first insulative layer 21b, the package unit 3b and the substrate unit 1b by evaporating, sputtering, electroplating or electroless plating.

Step S210 is: referring to FIGS. 3 and 3F, removing one part of the first conductive material C1b to form a first conductive unit 4b that has a plurality of first conductive layers 40b, two of the first conductive layers 40b being formed on the at least two semiconductor chips 20b, and end sides of the other first conductive layers 40b being respectively and electrically connected to the conductive pads 20b. The first conductive unit 4b is a UBM (Under Bump Metallization). In addition, the one part of the first conductive material C1b is removed by matching an exposure process, a development process and an etching process.

Step S212 is: referring to FIGS. 3 and 3G, forming a second conductive material C2b on the first conductive unit 4b. In addition, the second conductive material C2b is formed on the first conductive unit 4b by evaporating, sputtering, electroplating or electroless plating.

Step S214 is: referring to FIGS. 3 and 3H, removing one part of the second conductive material C2b to form a second conductive unit 5b that has a plurality of second conductive layers 50b, two of the second conductive layers 50b being formed on the two first conductive layers 40b that have been formed on the at least two semiconductor chips 2b, and the other second conductive layers 50b being respectively and electrically connected to the first conductive layers 40b that have been respectively and electrically connected to the conductive pads 20b. In addition, the one part of the second conductive material C2b is removed by matching an exposure process, a development process and an etching process.

Step S216 is: referring to FIGS. 3 and 3I, forming a second insulative material B2b between the first conductive layers 40b, between the second conductive layers 50b, and on the second conductive unit 5b. In addition, the second insulative material B2b is formed by printing, coasting or spraying, and the second insulative material B2b is hardened by pre-curing.

Step S218 is: referring to FIGS. 3 and 3J, removing one part of the second insulative material B2b to form a second insulative unit 6b that has a plurality of second insulative layers 60b between the first conductive layers 40b, between the second conductive layers 50b, and on the second conductive unit 5b in order to insulate the first conductive layers 40b from each other and insulate the second conductive layers 50b from each other. In addition, the one part of the second insulative material B2b is removed by matching an exposure process, a development process and an etching process to form the second insulative layers 60b that are hardened by curing.

Step S220 is: referring to FIGS. 3 and 3K, forming at least two semiconductor chip package structures (P1b, P2b) by a cutting process along the dotted line Y-Y in FIG. 3J. In other words, the at least two semiconductor chip package structures (P1b, P2b) are formed by cutting the second conductive unit 5b, the first conductive unit 4b, the substrate unit 1b and the package unit 3b in sequence.

Therefore, each semiconductor chip package structure (P1b, P2b) has a package unit 3b′, a semiconductor chip 2b, a substrate unit lb′, a first insulative unit, a first conductive unit 4b′, a second conductive unit 5b′, and a second insulative unit 6b′.

The package unit 3b′ has at least one central receiving groove 30b′ and at least one outer receiving groove 31b′ formed around the at least one central receiving groove 30b′. The semiconductor chip 2b is received in the at least one central receiving groove 30b′ and has a plurality of conductive pads 20b disposed on its top surface. The substrate unit 1b′ is received in the at least one outer receiving groove 31b′. The first insulative unit has at least one first insulative layer 21b formed between the conductive pads 20b in order to insulate the conductive pads 20b from each other.

Moreover, the first conductive unit 4b′ has a plurality of first conductive layers (40b, 40b′). One of the first conductive layers 40b is formed on the at least one first insulative layer 21b and over the at least one semiconductor chip 2b, and end sides of the other first conductive layers (40b, 40b′) are respectively and electrically connected to the conductive pads 20b. The second conductive unit 5b′ has a plurality of second conductive layers (50b, 50b′). One of the second conductive layer 50b is formed on the first conductive layer 40b that has been formed over the at least one semiconductor chip 2b, and the other second conductive layers (50b, 50b′) are respectively and electrically connected to the first conductive layers (40b, 40b′) that have been respectively and electrically connected to the conductive pads 20b.

Furthermore, the second insulative unit 6b′ has a plurality of second insulative layers 60b that are formed between the first conductive layers (40b, 40b′) and between the second conductive layers (50b, 50b′) in order to insulate the first conductive layers (40b, 40b′) from each other and insulate the second conductive layers (50b, 50b′) from each other. In addition, one part of each second insulative layer 60b is covering the second conductive layers (50b, 50b′).

Moreover, there are some different choices of the semiconductor chips 2a and the package unit 3a in the first embodiment, as follows:

1. Each semiconductor chip 2a can be an LED (light-emitting diode) chip set, and the package unit 3a can be made from fluorescent material. The conductive pads 20a of each semiconductor chip 2a are divided into a positive pad 200a and a negative pad 201a. For example, the LED chip set has a blue LED chip. Therefore, the match of the blue LED chip and the fluorescent material can generate white light.

2. Each semiconductor chip 2a can be an LED (light-emitting diode) chip set, and the package unit 3a can be made from transparent material. The conductive pads 20a of each semiconductor chip 2a are divided into a positive pad 200a and a negative pad 201a. For example, the LED chip set is an LED chip set for generating white light (such as the LED chip set is composed of a red LED chip, a green LED chip and a blue LED chip). Therefore, the match of the LED chip set for generating white light and the transparent material can generate white light.

3. Each semiconductor chip 2a can be a light-sensing chip or an image-sensing chip, and the package unit 3a can be made from transparent material or translucent material. The conductive pads 20a of each semiconductor chip 2a at least are divided into a pad set and a signal pad set.

4. Each semiconductor chip 2a can be an IC (Integrated Circuit) chip, and the package unit 3a can be made from opaque material. The conductive pads 20a of each semiconductor chip 2a at least are divided into a pad set and a signal pad set.

Although the present invention has been described with reference to the preferred best molds thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A semiconductor chip package structure for achieving face-up electrical connection without using a wire-bonding process, comprising:
a package unit having at least one central receiving groove and at least one outer receiving groove formed around the at least one central receiving groove;
at least one semiconductor chip received in the at least one central receiving groove and having a plurality of conductive pads disposed on its top surface;
a substrate unit received in the at least one outer receiving groove;
a first insulative unit having at least one first insulative layer formed between the conductive pads in order to insulate the conductive pads from each other;
a first conductive unit having a plurality of first conductive layers, wherein one of the first conductive layers is formed on the at least one first insulative layer and over the at least one semiconductor chip, and end sides of the other first conductive layers are respectively and electrically connected to the conductive pads;
a second conductive unit having a plurality of second conductive layers, wherein one of the second conductive layer is formed on the first conductive layer that has been formed over the at least one semiconductor chip, and the other second conductive layers are respectively and electrically connected to the first conductive layers that have been respectively and electrically connected to the conductive pads; and
a second insulative unit formed between the first conductive layers and between the second conductive layers in order to insulate the first conductive layers from each other and insulate the second conductive layers from each other.

2. The semiconductor chip package structure as claimed in claim 1, wherein the at least one semiconductor chip is an LED chip set, the package unit is made from fluorescent material or transparent material, the conductive pads are divided into a positive pad and a negative pad, and the semiconductor chip has a light-emitting surface on its bottom surface and opposite to the conductive pads.

3. The semiconductor chip package structure as claimed in claim 1, wherein the at least one semiconductor chip is a light-sensing chip or an image-sensing chip, the package unit is made from transparent material or translucent material, and the conductive pads are divided into a pad set and a signal pad set.

4. The semiconductor chip package structure as claimed in claim 1, wherein the at least one semiconductor chip is an IC (Integrated Circuit) chip, the package unit is made from opaque material, and the conductive pads are divided into a pad set and a signal pad set.

5. The semiconductor chip package structure as claimed in claim 1, wherein the first conductive layers that have been respectively and electrically connected to the conductive pads are formed on the package unit and the substrate unit.

6. The semiconductor chip package structure as claimed in claim 1, wherein one part of the second insulative unit is covering the second conductive layers.

7. A method of making semiconductor chip package structures for achieving face-up electrical connection without using a wire-bonding process, comprising:
providing at least two semiconductor chips, wherein each semiconductor chip has a plurality of conductive pads;
adhering an adhesive polymeric material on a bottom surface of a substrate unit with at least two through holes;
arranging the at least two semiconductor chips in the at least two through holes and on the adhesive polymeric material, wherein the conductive pads face the adhesive polymeric material;
covering the substrate, the adhesive polymeric material and the at least two semiconductor chips with a package unit;
overturning the package unit and removing the adhesive polymeric material in order to make the conductive pads exposed face-up;
forming a first conductive unit having a plurality of first conductive layers, wherein two of the first conductive layers is formed on the at least two semiconductor chips, and end sides of the other first conductive layers are respectively and electrically connected to the conductive pads;
forming a second conductive unit having a plurality of second conductive layers, wherein two of the second conductive layers is formed on the two first conductive layers that have been formed on the at least two semiconductor chips, and the other second conductive layers are respectively and electrically connected to the first conductive layers that have been respectively and electrically connected to the conductive pads;
forming an insulative unit having a plurality of insulative layers, wherein the insulative unit is formed between the first conductive layers and between the second conductive layers in order to insulate the first conductive layers from each other and insulate the second conductive layers from each other; and
cutting the second conductive unit, the first conductive unit, the substrate unit and the package unit in sequence in order to form at least two semiconductor chip package structures.

8. The method as claimed in claim 7, wherein each semiconductor chip is an LED chip set, the package unit is made from fluorescent material or transparent material, the conductive pads of each semiconductor chip are divided into a positive pad and a negative pad, and each semiconductor chip has a light-emitting surface on its bottom surface and opposite to the conductive pads.

9. The method as claimed in claim 7, wherein each semiconductor chip is a light-sensing chip or an image-sensing chip, the package unit is made from transparent material or translucent material, and the conductive pads of each semiconductor chip are divided into a pad set and a signal pad set.

10. The method as claimed in claim 7, wherein each semiconductor chip is an IC (Integrated Circuit) chip, the package unit is made from opaque material, and the conductive pads of each semiconductor chip are divided into a pad set and a signal pad set.

11. The method as claimed in claim 7, wherein the step of providing the at least two semiconductor chips further comprises:
forming a first insulative material on the semiconductor chips and on the conductive pads; and
removing one part of the first insulative material to form the at least one first insulative layer for exposing the conductive pads;
wherein the first insulative material is formed on the semiconductor chips and on the conductive pads by printing, coasting or spraying, and the first insulative material is hardened by pre-curing and the one part of the first insulative material is removed by matching an exposure process, a development process and an etching process.

12. The method as claimed in claim 7, wherein the step of forming the first conductive layers and the second conductive layers further comprises:
forming a first conductive material on the semiconductor chips, the package unit and the substrate unit;
removing one part of the first conductive material to form the first conductive layers respectively and electrically connected to the conductive pads;
forming a second conductive material on the first conductive layers; and
removing one part of the second conductive material to form the second conductive layers;
wherein the first conductive material and the second conductive material are formed by evaporating, sputtering, electroplating or electroless plating, and the one part of the first conductive material and the one part of the second conductive material are removed by matching an exposure process, a development process and an etching process.

13. A semiconductor chip package structure for achieving face-up electrical connection without using a wire-bonding process, comprising:
a package unit having at least one central receiving groove and at least one outer receiving groove formed around the at least one central receiving groove;
at least one semiconductor chip received in the at least one central receiving groove and having a plurality of conductive pads disposed on its top surface;
a substrate unit received in the at least one outer receiving groove;
a first conductive unit having a plurality of first conductive layers, wherein one of the first conductive layers is formed on the at least one semiconductor chip, and end sides of the other first conductive layers are respectively and electrically connected to the conductive pads;
a second conductive unit having a plurality of second conductive layers, wherein one of the second conductive layer is formed on the first conductive layer that has been formed on the at least one semiconductor chip, and the other second conductive layers are respectively and electrically connected to the first conductive layers that have been respectively and electrically connected to the conductive pads; and
an insulative unit formed between the first conductive layers and between the second conductive layers in order to insulate the first conductive layers from each other and insulate the second conductive layers from each other.

14. The semiconductor chip package structure as claimed in claim 13, wherein the at least one semiconductor chip is an LED chip set, the package unit is made from fluorescent material or transparent material, the conductive pads are divided into a positive pad and a negative pad, and each semiconductor chip has a light-emitting surface on its bottom surface and opposite to the conductive pads.

15. The semiconductor chip package structure as claimed in claim 13, wherein the at least one semiconductor chip is a light-sensing chip or an image-sensing chip, the package unit is made from transparent material or translucent material, and the conductive pads are divided into a pad set and a signal pad set.

16. The semiconductor chip package structure as claimed in claim 13, wherein the at least one semiconductor chip is an IC (Integrated Circuit) chip, the package unit is made from opaque material, and the conductive pads are divided into a pad set and a signal pad set.

17. The semiconductor chip package structure as claimed in claim 13, wherein the first conductive layers that have been respectively and electrically connected to the conductive pads are formed on the package unit, the substrate unit and the at least one semiconductor chip.

18. The semiconductor chip package structure as claimed in claim 13, wherein one part of the insulative unit is covering the second conductive layers.
